(19) United States
(12) Patent Application Publication
(10) Pub. No.: US 2026/0282466 A1
(43) Pub. Date: Sep. 17, 2026

(54) TRANSISTORS INCLUDING CURVED AIR GAPS

(71) Applicant: GlobalFoundries Singapore Pte. Ltd., Singapore (SG)

(72) Inventors: WENSHENG DENG, Singapore (SG); WANBING YI, Singapore (SG); KEMAO LIN, Singapore (SG); XIN CHEN, Singapore (SG); DAU FATT LIM, Singapore (SG); JU DY LIM, Singapore (SG); MENGTIAN HU, Singapore (SG)

(21) Appl. No.: 19/079,498

(22) Filed: Mar. 14, 2025

(51) Int. Cl. H10D 62/10; H10D 64/23; H10D 64/27; H10D 64/68

(52) U.S. Cl. CPC H10D 62/115; H10D 62/102; H10D 64/256; H10D 64/516; H10D 64/681

(57) ABSTRACT

The embodiments herein relate to transistors including curved air gaps and methods of forming the same. The transistor includes a substrate, a gate electrode, a source/drain region, and an air gap. The gate electrode is over the substrate. The source/drain region is in the substrate adjacent to the gate electrode. The air gap is over the substrate adjacent to the gate electrode. The air gap includes a lateral portion over the source/drain electrode and a vertical portion between the lateral portion of the air gap and the gate electrode.

### TECHNICAL FIELD

The present disclosure relates generally to semiconductor devices, and more particularly to transistors including curved air gaps and methods of forming the same.

### BACKGROUND

Advancements in the semiconductor integrated circuit (IC) industry have led to smaller IC chips with a higher density of semiconductor devices. Miniaturization, or downsizing, is key to improving overall device performance. As semiconductor devices continue to shrink in size, parasitic capacitive coupling between adjacent electrically conductive elements also increases. The rise in parasitic capacitive coupling negatively impacts the overall performance of the semiconductor devices.

Accordingly, to meet the growing needs of the semiconductor industry, semiconductor devices enabling further device miniaturization without penalizing device performance and methods of forming the same are provided.

### SUMMARY

To achieve the foregoing and other aspects of the present disclosure, transistors including curved air gaps and methods of forming the same are presented.

According to an aspect of the present disclosure, a transistor is provided. The transistor includes a substrate, a gate electrode, a source/drain region, and an air gap. The gate electrode is over the substrate. The source/drain region is in the substrate adjacent to the gate electrode. The air gap is over the substrate adjacent to the gate electrode. The air gap includes a lateral portion over the source/drain electrode and a vertical portion between the lateral portion of the air gap and the gate electrode.

According to another aspect of the present disclosure, a method of forming a transistor is provided. The method includes forming a gate electrode over a substrate and forming a source/drain region in the substrate. The source/drain region is adjacent to the gate electrode. An air gap is formed over the substrate adjacent to the gate electrode, wherein the air gap includes a lateral portion over the source/drain region and a vertical portion between the lateral portion of the air gap and the gate electrode.

### BRIEF DESCRIPTION OF THE DRAWINGS

The embodiments of the present disclosure will be better understood from a reading of the following detailed description, taken in conjunction with the accompanying drawings.

FIGS. 1-5 are cross-sectional views of a transistor at successive fabrication stages of a processing method, according to an embodiment of the disclosure.

For simplicity and clarity of illustration, the drawings illustrate the general manner of construction, and certain descriptions and details of features and techniques may be omitted to avoid unnecessarily obscuring the discussion of the described embodiments of the device.

Additionally, elements in the drawings are not necessarily drawn to scale. For example, the dimensions of some of the elements in the drawings may be exaggerated relative to other elements to help improve understanding of embodiments of the device. The same reference numerals in different drawings denote the same elements, while similar reference numerals may, but do not necessarily, denote similar elements.

### DETAILED DESCRIPTION

The present disclosure relates to semiconductor devices, and more particularly to transistors including curved air gaps and methods of forming the same. Air gaps, or sealed voids, may be used to improve electrical isolation between the electrically conductive elements of the transistors, reducing the level of parasitic capacitance therebetween, thereby improving the overall performance of the transistors.

Various embodiments of the present disclosure are now described in detail with accompanying drawings. It is noted that like and corresponding elements are referred to by the use of the same reference numerals. The embodiments disclosed herein are exemplary, and not intended to be exhaustive or limiting to the disclosure.

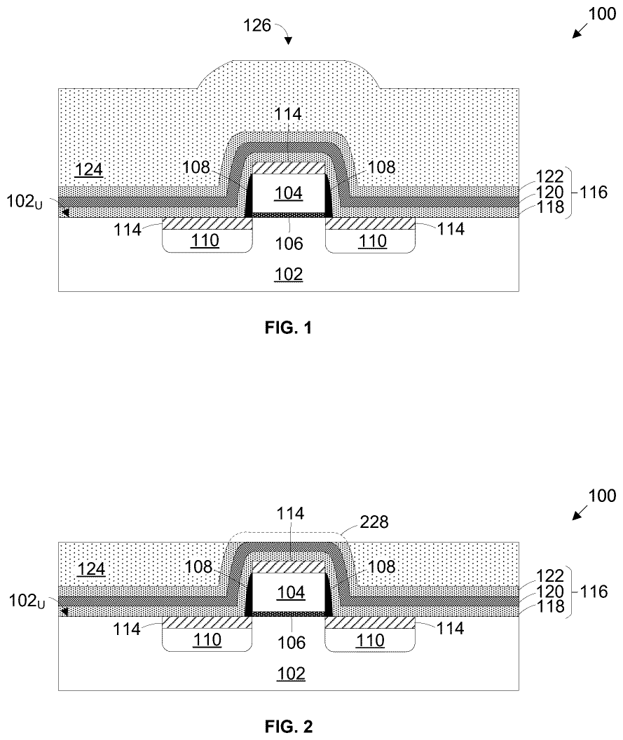

FIGS. 1 to 5 are cross-sectional views of a transistor 100 at successive fabrication stages of a processing method, according to an embodiment of the disclosure. The transistor 100 may be a metal-oxide-semiconductor field-effect transistor (MOSFET), either an n-channel FET (NFET) or a p-channel FET (PFET).

Certain structures may be fabricated, for example, using known processes and techniques, and specifically disclosed processes and methods may be used to achieve individual aspects of the present disclosure. The below-described order for the method of forming the transistor 100 is intended to be illustrative, and the method is not limited to the specifically described order unless otherwise specifically stated.

As used herein, “deposition process” refers to the techniques of applying a material over another material. Exemplary processes for deposition include, but not limited to, spin-on coating, sputtering, chemical vapor deposition (CVD), physical vapor deposition (PVD), molecular beam deposition (MBD), pulsed laser deposition (PLD), liquid source misted chemical deposition (LSMCD), or atomic layer deposition (ALD).

Additionally, “patterning process” includes the techniques of depositing material or photoresist, patterning, exposure, development, etching, cleaning, and/or removal of the material or photoresist as required in forming a described pattern, structure, or opening. Exemplary examples of processes for patterning include, but not limited to, wet etch photolithographic processes, dry etch photolithographic processes, or direct patterning processes.

Referring to FIG. 1, the transistor 100 may include a substrate 102 having an upper substrate surface 102_{U}. The substrate 102 may include a monocrystalline semiconductor material, such as silicon, silicon germanium, silicon carbide, or other II-VI or III-V semiconductor compounds. The substrate 102 may be a bulk semiconductor substrate, as illustrated, or a composite semiconductor substrate (not shown), such as a semiconductor-on-insulator (SOI) substrate including a base substrate, a buried insulator layer over the base substrate, and a semiconductor layer over the buried insulator layer.

The transistor 100 may further include a plurality of elements, such as a gate electrode 104 over the substrate 102, a gate dielectric layer 106 between the gate electrode 104 and the substrate 102, gate spacers 108 on opposite sides of the gate electrode 104, and source/drain regions 110 in the substrate 102 at an opposite side of the gate electrode 104. The gate electrode 104 and the source/drain regions 110 may each include an ohmic contact 114 arranged thereover. The ohmic contacts 114 of the source/drain regions 110 may be in the substrate 102. The ohmic contacts 114 may include a metal silicide compound, such as titanium silicide, nickel silicide, or cobalt silicide.

The gate electrode 104 may include a semiconductor material, such as polycrystalline silicon. The gate dielectric layer 106 and the gate spacers 108 may include an electrically insulative dielectric material, though not necessarily the same material, such as silicon oxide or silicon nitride. The source/drain regions 110 may include dopants whose dopant conductivity depends on the type of the transistor 100. For example, the dopants may include n-type conductivity dopants, such as arsenic, phosphorus, or antimony, for an NFET. In another example, the dopants may include p-type conductivity dopants, such as boron, aluminum, or gallium, for a PFET.

A multi-layered dielectric stack 116 may be arranged over the substrate 102. The dielectric stack 116 may lay conformally on the upper substrate surface 102_{U}, the gate spacers 108, and the respective ohmic contacts 114 of the gate electrode 104 and the source/drain regions 110. For example, the dielectric stack 116 may include a first substantially planar portion, i.e., a generally flat portion on a horizontal plane, on the upper substrate surface 102_{U}, a second substantially planar portion on the ohmic contact 114 over the gate electrode 104, and a curved portion laterally on the gate spacers 108 connecting the first substantially planar portion and the second substantially planar portion. The curved portion of the dielectric stack 116 may extend from laterally opposite sides of the gate electrode 104 from the second substantially planar portion towards the first substantially planar portion of the dielectric stack 116, and at least a section of the curved portion may be aligned vertically over the source/drain regions 110.

The dielectric stack 116 may include a bottom dielectric layer 118, a middle dielectric layer 120 over the bottom dielectric layer 118, and a top dielectric layer 122 over the middle dielectric layer 120. The middle dielectric layer 120 may be in direct contact with the bottom and top dielectric layers 118, 122 with no intervening materials. The bottom dielectric layer 118 may be directly in contact with the upper substrate surface 102_{U}, the gate spacers 108, and the respective ohmic contacts 114 of the gate electrode 104 and the source/drain regions 110. Even though FIG. 2 illustrates the bottom, middle, and top dielectric layers 118, 120, 122 as having relatively similar thicknesses, the thicknesses of the bottom, middle, and top dielectric layers 118, 120, 122 may be different. The thickness of the middle dielectric layer 120 may be taken to be the shortest dimension between the bottom dielectric layer 118 and the top dielectric layer 122.

The middle dielectric layer 120 may include a different dielectric material from the bottom dielectric layer 118 and/or the top dielectric layer 122. For example, the middle dielectric layer 120 may be preferred to provide a substantially high etch selectivity to the top dielectric layer 122 and the bottom dielectric layer 118. In an embodiment of the disclosure, the bottom and top dielectric layers 118, 122 may include the same dielectric material, such as silicon oxide, while the middle dielectric layer 120 may include silicon nitride. In this instance, the dielectric stack 116 may be commonly referred to as an oxide-nitride-oxide (ONO) stack. In another embodiment of the disclosure, the bottom, middle, and top dielectric layers 118, 120, 122 may include different dielectric materials.

The term “etch selectivity” as used herein refers to the material removal rate of one material relative to the material removal rate of another material, for example, the ratio of the material removal rate of the middle dielectric layer 120 to the material removal rate of the bottom and top dielectric layers 118, 122. The term “substantially high etch selectivity” as used herein refers to a characteristic between two materials, such that one material may be removed without substantially removing the other material during a material removal process. For example, the etch selectivity of the middle dielectric layer 120 with respect to the bottom and top dielectric layers 118, 122 may be in a ratio of 100:1, such that for every 100 nm of material removed from the middle dielectric layer 120, only 1 nm of material of the bottom and top dielectric layers 118, 122 is removed. Therefore, the bottom and top dielectric layers 118, 122 may be removed at a relatively much slower rate or remain substantially intact during the material removal process.

An interlayer dielectric (ILD) 124 may be arranged over the dielectric stack 116. The ILD 124 may include a dielectric material, such as silicon oxide, silicon oxynitride, borophosphosilicate glass (BPSG), or undoped silicate glass (USG), and may be formed from any number of dielectric layers. Due to the presence of elements over the upper substrate surface 102_{U}, such as the gate electrode 104, the surface topography of the transistor 100 may be non-planar and the transistor 100 may include a protrusion region 126 vertically over the gate electrode 104. In an embodiment of the disclosure, the ILD 124 and the top dielectric layer 122 may include the same dielectric material.

FIG. 2 is a cross-sectional view of the transistor 100 at a fabrication stage after FIG. 1, according to an embodiment of the disclosure. The transistor 100 may undergo a planarization process, such as a chemical-mechanical planarization/polishing (CMP) process. The planarization process may remove the non-planar surface topography of the transistor 100 at the protrusion region 126 to provide a substantially planar or flat surface topography. The planarization process may utilize an end-point detection system to stop the planarization process once a material different from the one being removed is detected. For example, since the ILD 124 and the top dielectric layer 122 may include the same dielectric material, the planarization process may continue until a portion of the middle dielectric layer 120 is exposed, resulting in an opening 228 formed through a part of the top dielectric layer 122, thereby triggering the end-point detection system to stop the planarization process. The outline of the opening 228 is diagrammatically shown by a dashed line for purposes of illustration. The exposed portion of the middle dielectric layer 120 may be aligned vertically over the gate electrode 104, and the opening 228 may divide the top dielectric layer 122 into disconnected portions on opposing sides of the gate electrode 104.

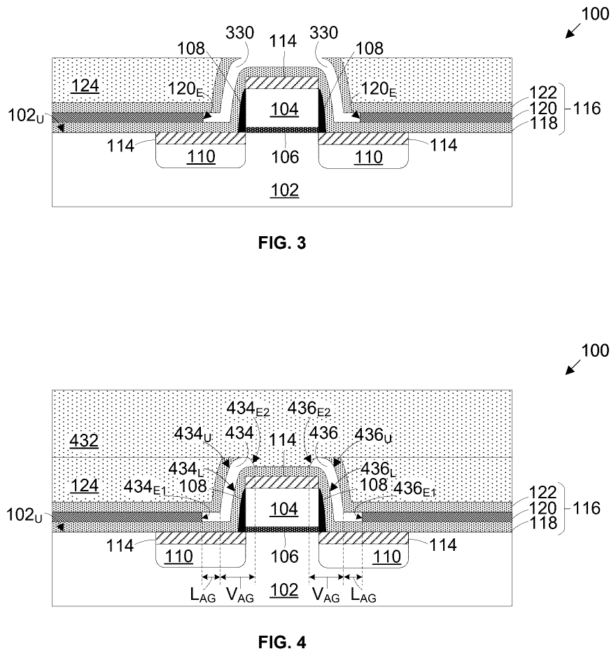

FIG. 3 is a cross-sectional view of the transistor 100 at a fabrication stage after FIG. 2, according to an embodiment of the disclosure. The transistor 100 may undergo a material removal process, including an etching process, to remove at least the exposed portion of the middle dielectric layer 120 through the opening 228 of the top dielectric layer 122.

As mentioned, the middle dielectric layer 120 may have a substantially high etch selectivity to the top dielectric layer 122 and the bottom dielectric layer 118. Accordingly, during the material removal process, the middle dielectric layer 120 may have a higher material removal rate as compared to the bottom and top dielectric layers 118, 122. The bottom and top dielectric layers 118, 122 may be removed at a relatively slower rate or remain substantially intact during the material removal process. The material removal process may begin to remove the exposed portion of the middle dielectric layer 120, and continue removing the middle dielectric layer 120 along the length thereof in a downward direction extending away from the gate electrode 104 to form a void 330 between the bottom and top dielectric layers 118, 122. The middle dielectric layer 120 may include end portions 120_{E} laterally adjacent to the gate electrode 104, and the end portions 120_{E} may be aligned vertically over the source/drain regions 110, spaced apart therefrom by the bottom dielectric layer 118. The end portions 120_{E} of the middle dielectric layer 120 may also define an outer boundary of the void 330 with respect to the gate electrode 104.

FIG. 4 is a cross-sectional view of the transistor 100 at a fabrication stage after FIG. 3, according to an embodiment of the disclosure. An ILD 432 may be formed on the ILD 124 using a non-conformal deposition process, such as a chemical vapor deposition (CVD) process. The ILD 432 may include a dielectric material, such as silicon oxide, silicon oxynitride, borophosphosilicate glass (BPSG), or undoped silicate glass (USG), and may be formed from any number of dielectric layers. In an embodiment of the disclosure, the ILD 432 may include the same dielectric material as the ILD 124.

The ILD 432 may seal the void 330 to form an air gap 434 and an air gap 436 at laterally opposite sides of the gate electrode 104. A portion of the ILD 432 may be in contact with the bottom dielectric layer 118. The air gaps 434, 436 may have a substantially uniform dimension, such as thickness, taken to be the shortest dimension between the bottom dielectric layer 118 and the top dielectric layer 122, and the dimension may be equal to the thickness of the middle dielectric layer 120. The air gaps 434, 436 may contain a gas at or near atmospheric pressure, or at sub-atmospheric pressure, for example, a partial vacuum. The elemental composition of the gas in the air gaps 434, 436 can include different gases and should not be construed as having any particular elemental composition, for example, any number and type of gases may be present in the air gaps 434, 436.

Each of the air gaps 434, 436 may be collectively surrounded by dielectric materials, such as the bottom, middle, top dielectric layers 118, 120, 122 and the ILD 432, defining boundaries of the air gaps 434, 436. For example, the air gap 434 may have an upper boundary 434_{U} defined by the top dielectric layer 122, a lower boundary 434_{L} under the upper boundary 434_{U} defined by the bottom dielectric layer 118, an end boundary 434_{E1} aligned vertically over one of the source/drain regions 110 defined by the middle dielectric layer 120, and an end boundary 434_{E2} aligned vertically over the gate electrode 104 defined by the ILD 432. The end boundaries 434_{E1}, 434_{E2} may connect the upper and lower boundaries 434_{U}, 434_{L} of the air gap 434, and may define the respective outer boundary and the inner boundary of the air gap 434 with respect to the gate electrode 104. The end boundary 434_{E1} may be conterminous with the end portion 120_{E} of the middle dielectric layer 120. The end boundary 434_{E2} of the air gap 434 is laterally offset from and at a level, i.e., height, above the end boundary 434_{E1}.

The air gap 436 may also have similar boundaries as the air gap 434. For example, the air gap 436 may also have an upper boundary 436_{U} defined by the top dielectric layer 122, a lower boundary 436_{L} under the upper boundary 436_{U} defined by the bottom dielectric layer 118, an end boundary 436_{E1} aligned vertically over one of the source/drain regions 110 defined by the middle dielectric layer 120, and an end boundary 436_{E2} aligned vertically over the gate electrode 104 defined by the ILD 432. The end boundaries 436_{E1}, 436_{E2} may connect the upper and lower boundaries 436_{U}, 436_{L} of the air gap 436, and may define the respective outer boundary and the inner boundary of the air gap 436 with respect to the gate electrode 104. The end boundary 436_{E1} may be conterminous with the end portion 120_{E} of the middle dielectric layer 120. The end boundary 436_{E2} of the air gap 436 is laterally offset from and at a level, i.e., height, above the end boundary 436_{E1}.

Each of the air gaps 434, 436 may include a lateral portion L_{AG} including the respective end boundaries 434_{E1}, 436_{E1}, and a vertical portion V_{AG} including the respective end boundaries 434_{E2}, 436_{E2} laterally connected to and extending from the lateral portions L_{AG} to a level thereabove. The vertical portions V_{AG} may be between the corresponding lateral portions L_{AG} and the gate electrode 104, and may further extend to a level, i.e., height, above the gate electrode 104. For example, the end boundaries 434_{E2}, 436_{E2} of the air gaps 434, 436 may have an overlapping arrangement with, or in substantially vertical alignment to, the gate electrode 104 and the ohmic contact 114 thereof. In another example, the end boundaries 434_{E2}, 436_{E2} of the air gaps 434, 436 may be arranged in a laterally offset from the gate electrode 104 while at a level, i.e., height, above the gate electrode 104.

The lateral portions L_{AG} of the air gaps 434, 436 may be substantially planar, i.e., generally flat on a horizontal plane, and may be aligned vertically on the ohmic contacts 114 over the source/drain regions 110. The upper boundaries 434_{U}, 436_{U} and the lower boundaries 434_{L}, 436_{L} of the respective air gaps 434, 436 may be substantially uniformly spaced apart from each other. In an embodiment of the disclosure, each of the lateral portions L_{AG} of the air gaps 434, 436 may be fully within the boundary of the proximate ohmic contact 114 of the source/drain regions 110.

The vertical portion V_{AG} of each air gap 434, 436 may be curved. For example, the lower boundary 434_{L} and the upper boundary 434_{U} of the vertical portion V_{AG} of the air gap 434 may be curved in a same direction away from the gate electrode 104, while the lower boundary 436_{L} and the upper boundary 436_{U} of the vertical portion V_{AG} of the air gap 436 may be curved in an opposite direction away from the gate electrode 104. In another example, each of the lower boundaries 434_{L}, 436_{L} of the vertical portions V_{AG} of the air gaps 434, 436 may include a convex surface of the bottom dielectric layer 118 extending outwardly away from the gate electrode 104 and each of the upper boundaries 434_{U}, 436_{U} of the vertical portions V_{AG} of the air gaps 434, 436 may include a concave surface of the top dielectric layer 122 extending inwardly away from the gate electrode 104. The upper boundaries 434_{U}, 436_{U} of the vertical portions V_{AG} of the air gaps 434, 436 may be substantially uniformly spaced apart from the corresponding lower boundaries 434_{L}, 436_{L} of the respective air gaps 434, 436, curved in a substantially parallel orientation. In an embodiment of the disclosure, the upper boundaries 434_{U}, 436_{U} and the lower boundaries 434_{L}, 436_{L} may be adjacent to and in contact with the same dielectric material, such as silicon oxide.

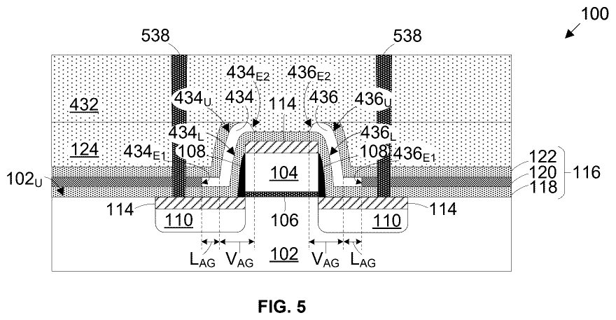

FIG. 5 is a cross-sectional view of the transistor 100 at a fabrication stage after FIG. 4, according to an embodiment of the disclosure. Contacts 538 may be formed adjacent to the air gaps 434, 436 over the source/drain regions 110. The contacts 538 may be formed using a patterning process, including lithography and etching processes to form contact openings (not shown) through the ILD 432, ILD 124, and the dielectric stack 116, and a deposition process, including a CVD process, to deposit an electrically conductive material, such as copper or tungsten, in the contact openings.

The contacts 538 may extend through the ILD 432, the ILD 124, and the dielectric stack 116 to be electrically connected to the source/drain regions 110 through the respective ohmic contacts 114. The top dielectric layer 122, the middle dielectric layer 120, and the bottom dielectric layer 118 of the dielectric stack 116 may laterally surround the contacts 538. The contacts 538 may be spaced apart from the lateral portions L_{AG} of the air gaps 434, 436 by a portion of the middle dielectric layer 120, including the end portions 120_{E1}.

As presented above, transistors including curved air gaps and methods of forming the same are disclosed. The curved air gaps may include a planar lateral portion over source/drain regions and a curved vertical between the lateral portion and a gate electrode. The curved vertical portion may be laterally connected to and extending from the lateral portion to a level above an ohmic contact of the gate electrode. The curved air gaps may include an upper boundary, a lower boundary, a first end portions defined by a first dielectric material, and a second end portion defined by a second dielectric material. The first end portion may be over the gate electrode, while the second end portion may be vertically over the source/drain regions and at a level below the first end portion. The curved air gaps may provide electrical isolation between the gate electrode and adjacent conductive elements, such as contacts over the source/drain regions.

The terms “top”, “bottom”, “over”, “under”, and the like in the description and the claims, if any, are used for descriptive purposes and not necessarily for describing permanent relative positions. It is to be understood that the terms so used are interchangeable under appropriate circumstances such that the embodiments of the devices described herein are, for example, capable of operation in other orientations than those illustrated or otherwise described herein.

Additionally, the formation of a first feature over or on a second feature in the description that follows may include embodiments in which the first and second features are formed in direct contact and may also include embodiments in which additional features may be formed by interposing the first and second features, such that the first and second features may not be in direct contact.

Similarly, if a method is described herein as involving a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of features is not necessarily limited to those features but may include other features not expressly listed or inherent to such process, method, article, or device. Occurrences of the phrase “in an embodiment” herein do not necessarily all refer to the same embodiment.

In addition, unless otherwise indicated, all numbers expressing quantities, ratios, and numerical properties of materials, reaction conditions, and so forth used in the specification and claims are to be understood as being modified in all instances by the term “about”.

Furthermore, approximating language, as used herein throughout the specification and claims, may be applied to modify any quantitative representation that could permissibly vary without resulting in a change in the basic function to which it is related. Accordingly, a value modified by a term or terms, such as “approximately”, “about,” or “substantially” is not limited to the precise value specified. In some instances, the approximating language may correspond to the precision of an instrument for measuring the value. In other instances, the approximating language may correspond to within normal tolerances of the semiconductor industry. For example, “substantially coplanar” means substantially in a same plane within normal tolerances of the semiconductor industry, and “substantially perpendicular” means at an angle of 90 degrees plus or minus a normal tolerance of the semiconductor industry.

While several exemplary embodiments have been presented in the above-detailed description of the device, it should be appreciated that a number of variations exist. It should further be appreciated that the embodiments are only examples, and are not intended to limit the scope, applicability, dimensions, or configuration of the device in any way. Rather, the above-detailed description will provide those skilled in the art with a convenient road map for implementing an exemplary embodiment of the device, it is understood that various changes may be made in the function and arrangement of features and methods of fabrication described in an exemplary embodiment without departing from the scope of this disclosure as set forth in the appended claims.

What is claimed is:

1. A transistor, comprising:
a gate electrode over a substrate;
a source/drain region in the substrate adjacent to the gate electrode; and
an air gap over the substrate adjacent to the gate electrode, wherein the air gap includes a lateral portion over the source/drain region and a vertical portion between the lateral portion of the air gap and the gate electrode.

2. The transistor of claim 1, wherein the vertical portion of the air gap extends from the lateral portion to a level above the gate electrode.

3. The transistor of claim 2, wherein the lateral portion of the air gap is substantially planar and the vertical portion of the air gap is curved.

4. The transistor of claim 3, wherein the vertical portion of the air gap includes an upper curved boundary and a lower curved boundary under the upper curved boundary, wherein the upper curved boundary and the lower curved boundary are connected at an end boundary.

5. The transistor of claim 4, wherein the upper curved boundary and the lower curved boundary are curved in a same direction away from the gate electrode.

6. The transistor of claim 5, wherein the upper curved boundary is substantially uniformly spaced apart from the lower curved boundary.

7. The transistor of claim 5, wherein the upper curved boundary and the lower curved boundary are adjacent to silicon oxide.

8. The transistor of claim 5, wherein the end boundary is a first end boundary, further comprising a second end boundary, wherein the first end boundary is over the gate electrode and the second end boundary is over the source/drain region.

9. The transistor of claim 8, wherein the second end boundary is at a level above the first end boundary.

10. The transistor of claim 8, wherein the first end boundary is adjacent to a first dielectric material and the second end boundary is adjacent to a second dielectric material different from the first dielectric material.

11. The transistor of claim 10, wherein the second dielectric material is silicon nitride.

12. The transistor of claim 10, further comprising a contact over the source/drain region, wherein the contact is laterally surrounded by the first dielectric material and the second dielectric material, and the second dielectric material is vertically between the first dielectric material.

13. The transistor of claim 12, wherein the contact is laterally spaced apart from the air gap by the second dielectric material.

14. The transistor of claim 13, wherein the air gap is collectively surrounded by dielectric materials.

15. A method of forming a transistor, comprising:
forming a gate electrode over a substrate;
forming a source/drain region in the substrate, wherein the source/drain region is adjacent to the gate electrode; and
forming an air gap over the substrate adjacent to the gate electrode, wherein the air gap includes a lateral portion over the source/drain region and a vertical portion between the lateral portion of the air gap and the gate electrode.

16. The method of claim 15, wherein forming the air gap comprises:
forming a dielectric stack over the substrate and the gate electrode, wherein the dielectric stack comprises a first dielectric layer, a second dielectric layer over the first dielectric layer, and a third dielectric layer over the second dielectric layer, wherein the second dielectric layer comprises a different dielectric material from the first dielectric layer and the second dielectric layer;
forming a void between the first dielectric layer and the second dielectric layer; and
sealing the void with a dielectric layer over the dielectric stack to form the air gap, wherein the air gap is collectively surrounded by dielectric materials.

17. The method of claim 16, wherein the air gap is formed having the vertical portion extending from the lateral portion to a level above the gate electrode, wherein the lateral portion is substantially planar and the vertical portion is curved.

18. The method of claim 16, wherein the vertical portion of the air gap includes an upper curved boundary and a lower curved boundary under the upper curved boundary, wherein the upper curved boundary and the lower curved boundary are curved in a same direction away from the gate electrode and connected at an end boundary.

19. The method of claim 18, further comprising forming a contact over the source/drain region, wherein the contact is laterally surrounded by the second dielectric layer.

20. The method of claim 19, wherein the contact is laterally spaced apart from the air gap by a portion of the second dielectric layer.
